(19) United States
(12) Patent Application Publication
(10) Pub. No.: US 2010/0073483 A1
(43) Pub. Date: Mar. 25, 2010

(54) System and method for transmitting video from multiple video cameras over a single multiple pair, twisted pair cable

(75) Inventors: Alan J. Squillante, Kings Park, NY (US); Peter Kobsa, Floral Park, NY (US)

Correspondence Address: BODNER & O'ROURKE, LLP, 425 BROADHOLLOW ROAD, SUITE 108, MELVILLE, NY, 11747, US

(73) Assignee: Porta Systems Corporation, Syosset, NY (US)

(21) Appl. No.: 12/586,210

(22) Filed: Sep. 18, 2009

Related U.S. Application Data
(60) Provisional application No. 61/192,643, filed on Sep. 19, 2008.
(60) Provisional application No. 61/196,650, filed on Oct. 20, 2008.

(51) Int. Cl. H04N 7/18; H01R 9/05; H03H 7/42

(52) U.S. Cl. 348/159; 439/581; 348/E07.086; 333/25

(57) ABSTRACT

A system for transmitting video signals from multiple video cameras over one or more multiple pair, twisted pair cables includes several video cameras and a plurality of twisted pair-to-coax balun “T” devices connected to the video cameras by coaxial cables. The video cameras generate unbalanced video signals. The twisted pair-to-coax balun “T” devices are connected together in a “daisy chain” fashion by electrical cables having multiple twisted pairs of wires. The balun “T” devices convert the unbalanced video signals from the cameras to balanced video signals. The balanced video signals are transmitted over the multiple pair, twisted pair cables to a hub, which provides the video signals to one or more monitors, a DVR, a multiplexer or other device.

### CROSS-REFERENCE TO RELATED APPLICATIONS

This application is related to U.S. Provisional Application Ser. No. 61/192,643, which was filed on Sep. 19, 2008, and is entitled “System and Method for Transmitting Video from Multiple Video Cameras Over a Single Multiple Pair, Twisted Pair Cable” and U.S. Provisional Application Ser. No. 61/196,650, which was filed on Oct. 20, 2008, and is entitled “System and Method for Transmitting Video from Multiple Video Cameras Over a Single Multiple Pair, Twisted Pair Cable”, the disclosure of each of which is hereby incorporated by reference and on which priority is hereby claimed.

### BACKGROUND OF INVENTION

1. Field of the Invention

This invention relates to systems and methods for transmitting video signals from a video camera, such as in a surveillance system, for example.

2. Description of the Prior Art

Coaxial cables are the traditional media used for transmission of video signals, such as in a surveillance system, for example. Each coaxial cable can only transmit signals from a single standard CCTV (closed circuit television) camera. Coaxial cable tends to be more expensive than standard twisted pair cable such as the type meeting Category 3, 5, 5e and 6 cabling standards, which contain four twisted pairs of wires. Thus, in accordance with the present invention disclosed herein, using the above-mentioned twisted pair cables has the additional cost savings of being able to transmit four video signals over a single cable.

In the current state of the art, there are two common solutions for transmitting multiple video signals from multiple CCTV cameras to multiple DVR (digital video recorder) inputs or multiple monitors. The first common method is to run a coaxial cable from each camera to each input of a DVR or monitor. The second common method is shown in FIG. 1. In this method, a hub is used on each end of a four or other multiple pair count cable to concentrate the multiple video signals from multiple coaxial cables to multiple twisted pairs in a single cable.

### OBJECTS AND SUMMARY OF THE INVENTION

It is an object of the present invention to provide a system for transmitting video signals from multiple video cameras over a single, multiple pair, twisted pair cable.

It is another object of the present invention to provide a “T” connection between twisted pairs of wires and coaxial cables in a system for transmitting video signals from multiple video cameras over a single, multiple pair, twisted pair cable.

It is still another object of the present invention to provide a method for transmitting video signals from multiple video cameras in, for example, a surveillance system over a single, multiple pair, twisted pair cable.

It is a further object of the present invention to provide a twisted pair-to-coax balun “T” device for use in a system employing multiple video cameras, which allows the video signals from the cameras carried on coaxial cables to the balun “T” device to be transmitted over a single, multiple pair, twisted pair cable.

It is yet a further object of the present invention to provide a surveillance system which uses multiple video cameras which overcomes the inherent disadvantages of known surveillance systems.

In accordance with one form of the present invention, a video system for transmitting video signals from a plurality of video cameras includes a plurality of video cameras, where each video camera generates an unbalanced video signal. The video cameras are connected to a plurality of coaxial cables. Each coaxial cable carries an unbalanced video signal from the video camera to which it is connected.

The video system further includes a plurality of twisted pair-to-coax balun “T” devices. Each balun “T” device is connected to a respective coaxial cable of the plurality of coaxial cables, and receives the unbalanced video signal from a respective video camera. Each twisted pair-to-coax balun “T” device converts the unbalanced video signal from a respective video camera to a balanced video signal.

The video system of the present invention further includes at least one electrical cable containing multiple twisted pairs of wires interconnecting at least two balun “T” devices. The cable selectively receives on the twisted pairs of wires respective balanced video signals from the at least two balun “T” devices.

In accordance with the present invention, a method of transmitting video signals from a plurality of video cameras in a video system includes the step of generating by the plurality of video cameras unbalanced video signals. Another step in the method of the present invention is receiving the unbalanced video signals over coaxial cables by a plurality of twisted pair-to-coax balun “T” devices, where each twisted pair-to-coax balun “T” device includes a balun having an input and an output and a connector electrically coupled to the balun output.

A further step in the method of the present invention is converting the unbalanced video signal received by the respective “T” device to a balanced video signal and providing the balanced video signal on the connector. A further step in the method is connecting the connector to an electrical cable containing multiple twisted pairs of wires to receive on at least one of the twisted pairs of wires the respective balanced video signal from the corresponding twisted pair-to-coax balun “T” device to which the electrical cable is connected.

These and other objects, features and advantages of the present invention will be apparent from the following detailed description of illustrative embodiments thereof, which is to be read in connection with the accompanying drawings.

### BRIEF DESCRIPTION OF THE DRAWINGS

FIG. 1 is a block diagram of a conventional system for transmitting multiple video signals from multiple CCTV cameras to multiple digital video recorder inputs, or monitors, multiplexers or the like.

FIG. 2 is a block diagram of a system formed in accordance with the present invention which allows for multiple video cameras to transmit their video signals over a single multiple pair, twisted pair cable.

FIG. 3 is a block diagram of an alternative embodiment of the system of the present invention for transmitting video from multiple video cameras over a single multiple pair, twisted pair cable.

FIG. 4 is a circuit diagram of a twisted pair-to-coax balun “T” device formed in accordance with the present invention which is used in the system of the present invention shown in FIGS. 2 and 3.

FIG. 5 is a circuit diagram of an alternate embodiment of a twisted pair-to-coax balun

“T” device formed in accordance with the present invention which is used in the system of the present invention shown in FIGS. 2 and 3.

FIG. 6 is a block diagram of an alternate embodiment of the system shown in FIG. 2.

FIG. 7 is a block diagram of an alternate embodiment of the system shown in FIG. 3.

FIG. 8A is a circuit diagram of an alternate embodiment of a twisted pair-to-coax balun

“T” device formed in accordance with the present invention which is used in the system of the present invention shown in FIGS. 6 and 7.

FIG. 8B is a circuit diagram of a resistive load used in the twisted pair-to-coax balun “T” device of the present invention shown in FIG. 8A.

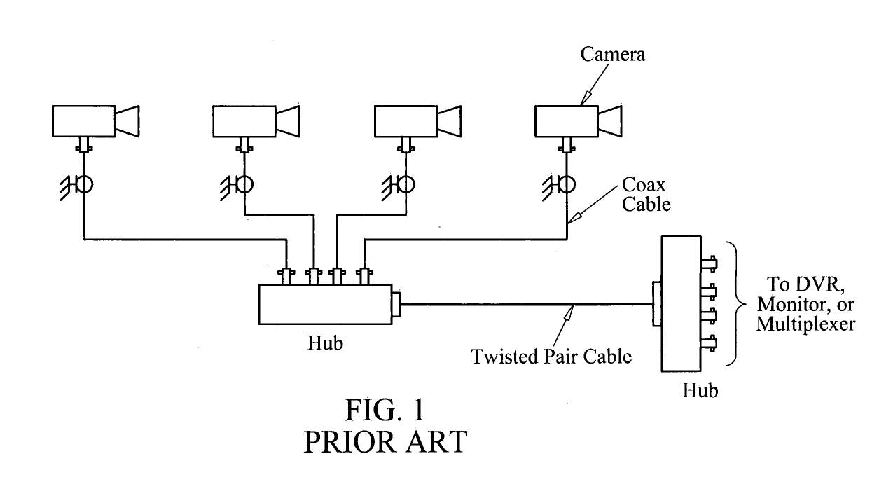

### DETAILED DESCRIPTION OF THE PREFERRED EMBODIMENTS

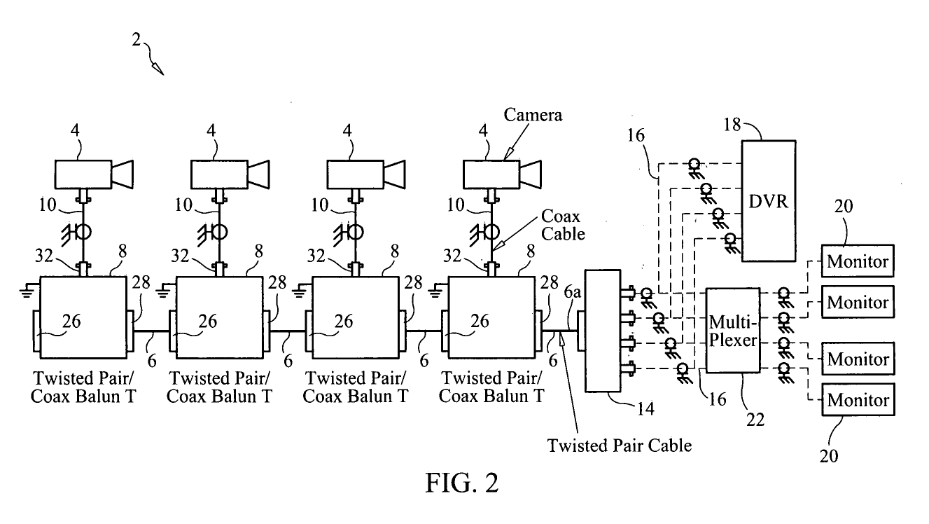

This invention is a system 2, such as a surveillance system, and method that allow for multiple video cameras 4 to transmit their video signals over a single multi-pair, twisted pair cable 6. The system uses one or more twisted pair-to-coax balun “T” devices 8. The twisted pair-to-coax balun “T” devices 8 that enable this system 2 to work as required are an integral part of this invention. An example of such a system 2 formed in accordance with the present invention is shown in FIG. 2. This exemplary system 2 has four CCTV cameras 4, although the invention can be configured for any number of multiple cameras 4 and twisted pair cables 6. Each of the four CCTV cameras 4 is connected to a twisted pair-to-coax balun “T” device 8 by a coaxial cable 10. The twisted pair-to-coax balun “T” device 8 converts the unbalanced coaxial video signal from a camera 4 to a balanced twisted pair signal and distributes the signal onto a user-chosen pair of wires or other transmission lines 12 within the device 8. Cables 6 with four twisted pairs of wires are connected between each of the twisted pair-to-coax balun “T” devices 8 in the system 2. Additionally, the last twisted pair-to-coax “T” device 8 in the system 2 is connected to a video hub 14. The video hub 14 converts each balanced twisted pair signal into an unbalanced coaxial signal. Each of the four unbalanced coaxial signals on the outputs of the video hub 14 is connected to a respective coaxial cable 16 that connects to one of four separate channels of a DVR (digital video recorder) 18 or other device, such as four separate monitors 20 or a multiplexer circuit 22 for cycling through each of a plurality of camera views.

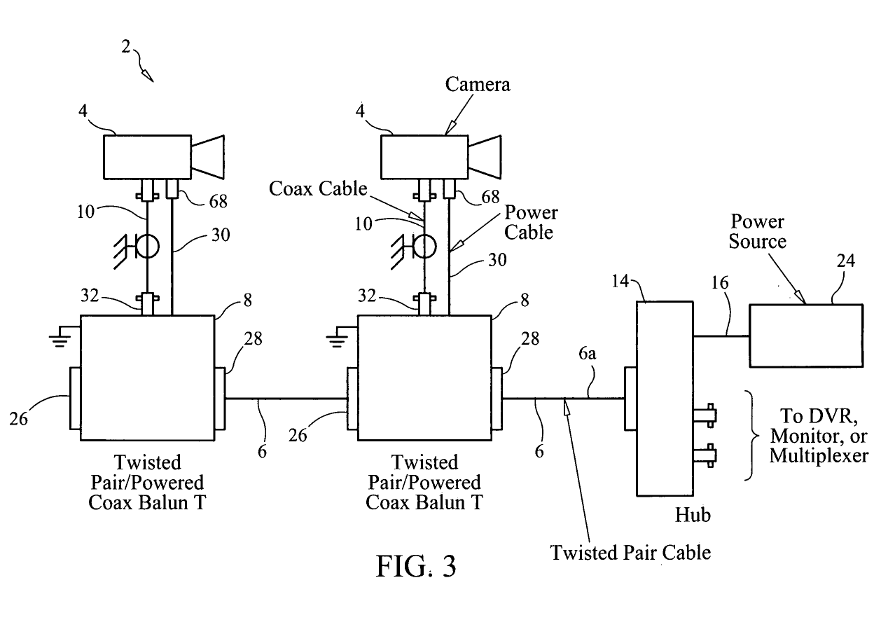

An alternative embodiment of the present invention is shown in FIG. 3. It can be seen from FIG. 3 that the system 2 includes twisted pair-to-coax balun “T” devices 8 that have a means to provide low voltage power to the cameras 4. A power source 24, generating a DC or AC voltage on its output, is connected using a coaxial cable or cables 16 to one or more inputs or outputs of the hub 14 which, in turn, causes the voltage to be placed on one or more twisted pairs of wires in the multiple pair, twisted pair cable 6 interconnecting the hub 14 and the twisted pair-to-coax balun “T” devices 8, as shown in FIG. 3. A coaxial cable input to the balun “T” device 8 is coupled via a coaxial cable 10 to a respective video camera 4, as in the embodiment shown in FIG. 2. However, the balun “T” device 8 for use in the embodiment shown in FIG. 3 uses one of its twisted pair inputs or outputs on the first connector 26 or the second connector 28 as a power output that is connected to the power input on the respective camera 4 with a power cable 30. The balun “T” device 8 provides the power signal (i.e., the voltage generated by the power source 24) on one or more of the twisted pairs of wires of the twisted pair cable 6 connected to its input/output connector 26, 28 to the camera 4 connected thereto to provide power to the camera. Other aspects and features of the system 2 shown in FIG. 3 are the same as or similar to those of the system 2 shown in FIG. 2, and like reference numbers used in the figures denote the same or similar components.

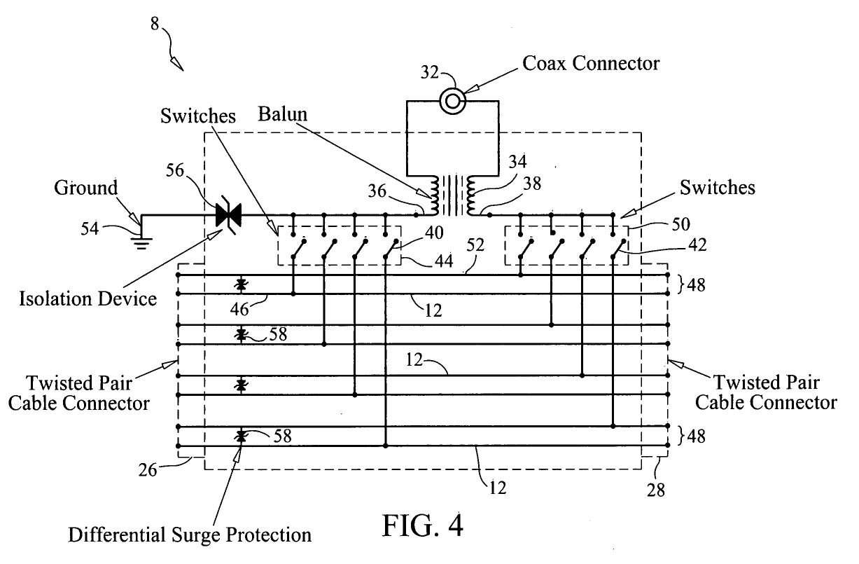

FIG. 4 shows one form of a twisted pair-to-coax balun “T” device 8 constructed in accordance with the present invention and used in the video systems 2 shown in FIGS. 2 and 3. The device 8 includes a first twisted pair cable connector 26 and a second twisted pair cable connector 28. Thus, two connections are made to four pair (or other multiple pair) cable 6. These connections allow the balanced video signals that typically have originated from other twisted pair-to-coax balun “T” devices 8 to pass through the device 8, although they can be any other type of compatible signals. The unbalanced signal from a camera 4 or other video device comes into the coaxial cable connector 32 of the device 8 as shown in FIG. 4. The “T” device 8 includes a balun 34 whose input is connected to the coaxial cable connector 32 and which converts this signal to a balanced signal on its output, the output having first and second output legs 36, 38, respectively.

There are several switches 40, 42 that form part of the “T” device 8 which are connected at one terminal thereof to one of the output legs 36, 38 of the balun 34. For example, and as shown in FIG. 4, each switch 40, 42 may be configured as a single pole, single throw (SPST) switch (or single pole, double throw (SPDT) switch). Preferably, and as shown in FIG. 4, each of four SPST switches 40 of a first group of switches 44 has one of its terminals connected to a first output leg 36 of the balun 34 and its other terminal connected to one wire or, more broadly, transmission line 46 of a pair 48 of wires or transmission lines of four pairs 48 of wires or transmission lines 12 within the device 8 which connect to the first and second twisted pair cable connectors 26, 28. Similarly, each of four SPST switches 42 of a second group of switches 50 has one of its terminals connected to a second output leg 38 of the balun 34 and its other terminal connected to the other wire or transmission line 52 of a pair 48 of wires or transmission lines of the four pairs 48 of wires or transmission lines within the device 8 which are connected to the twisted pair cable connectors 26, 28 mentioned previously. One of the switches 40, 42 of the first and second groups 44, 50 on each leg 36, 38 of the balun's balanced output can be closed by the user to route the video signal to a selected twisted pair of wires within the multiple pair, twisted pair cables 6 connected to the device 8 via the pairs 48 of wires or transmission lines 12 within the device 8 which are connected to the switches 40, 42. Alternatively, the switches 40, 42 can be factory set to route the video signal to a specific twisted pair of wires of the multiple twisted pair cables 6 connected to the device 8, or the connection can be accomplished in the factory using jumpers, or an alternative selection method, such as hard wiring the balun 34 to a chosen pair 48 of wires or transmission lines 12 within the device 8. Thus, switches 40, 42 of the first and second groups 44, 50 of switches which are connected to corresponding pairs 48 of wires or transmission lines 12 within the device 8 may be ganged together to define double pole, single throw (DPST) switches to allow the corresponding switches 40, 42 of the first and second groups 44, 50 to be thrown simultaneously by the user. The wires or transmission lines 12 within the balun “T” device 8 may be formed as conductive lands on a printed circuit board (not shown) within the device, and the two groups 44, 50 of switches may be mounted on the printed circuit board and connected to the conductive lands defining the transmission lines 12.

A ground connection 54 could be added to the device 8 to provide surge protection of the outer shield of the coaxial cable 10 connected to the device 8 from a camera 4. An isolation device 56, such as a Sidactor or the like, may be added between an output leg 36, 38 of the balun 34 and the ground to prevent ground loops and still provide surge protection on the coaxial line 10. Differential surge protectors 58, such as by using Sidactors or the like, can be added between the corresponding wires or transmission lines 46, 52 of each pair 48 of wires or transmission lines 12 within the device 8 to protect the twisted pair cables 6 connected to the device 8 from electrical surges.

Alternatively, some twisted pairs of wires within cable 6 can be used for video transmission, and other twisted pairs of wires within cable 6 for power. More specifically, two twisted pairs of wires of a four twisted pair cable 6 can be switched into the coaxial connections 32 through the balun 34 to carry video signals, and the other two twisted pairs of wires would be combined to carry power to a power cable 30 or directly to a power connector on the camera 4 in order to power the cameras, as described previously with respect to the video system shown in FIG. 3.

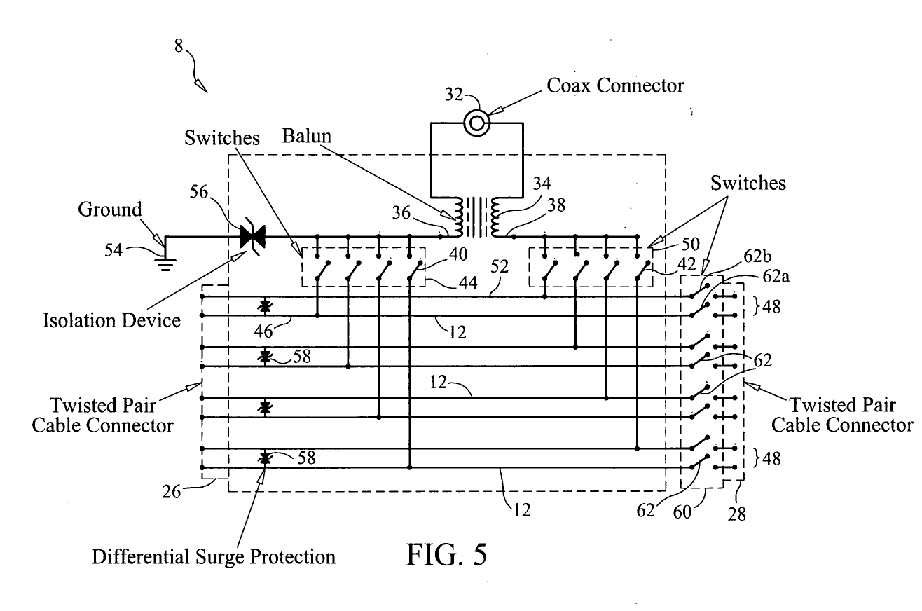

Alternatively, the connection between the first or second connector 26, 28 and the exiting twisted pair of wires in cable 6 that corresponds to the twisted pair of wires that is connected through the “T” device 8 to the selected CCTV camera 4 can be opened to improve video quality. This can be accomplished by adding an extra bank 60 (also referred to herein as a transmission line switch group) of DPST switches 62 (or double pole, double throw (DPDT) switches) as shown in FIG. 5, one DPST switch 62 being connected to a respective twisted pair of wires in the multiple pair, twisted pair cable 6. The DPST switches 62, on either cable connector 26, 28 of the balun “T” device 8, may be selectively and individually closed to provide a connection to the next balun “T” device 8 or to the hub 14 through the multiple pair, twisted pair cable 6, or may be opened when no further routing of signals through the respective device 8 is required and to minimize distortion of the video signal on a respective twisted pair of wires. Alternatively, the switches 62 can be factory set to open a specific twisted pair of wires in cable 6 connected to the device, 8 or the open circuit can be accomplished in the factory using jumpers, or an alternative selection method may be used, such as hard wiring the balun 34 to a chosen pair 48 of wires or transmission lines 12 within the device 8. Additionally, the SPST or DPST switches 40, 42 connected to the balun 34 and the DPST switches 62 that open the circuit to exiting pairs 48 of transmission lines 12 or wires can be ganged together to define quadruple pole, single throw (QPST) switches (or quadruple pole, double throw (QPDT) switches) that can accomplish both connecting the selected balun 34 to a video camera 4 and opening the corresponding selected pair 48 of transmission lines 12 or wires.

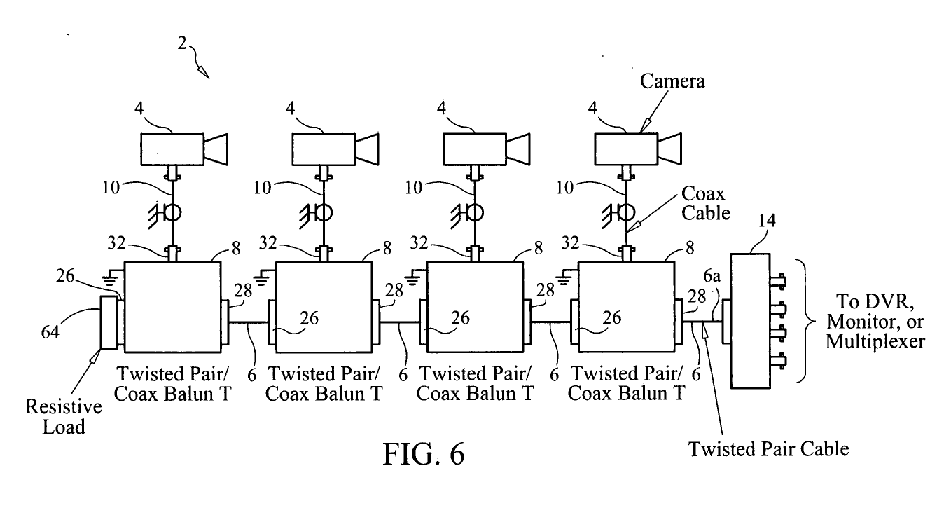

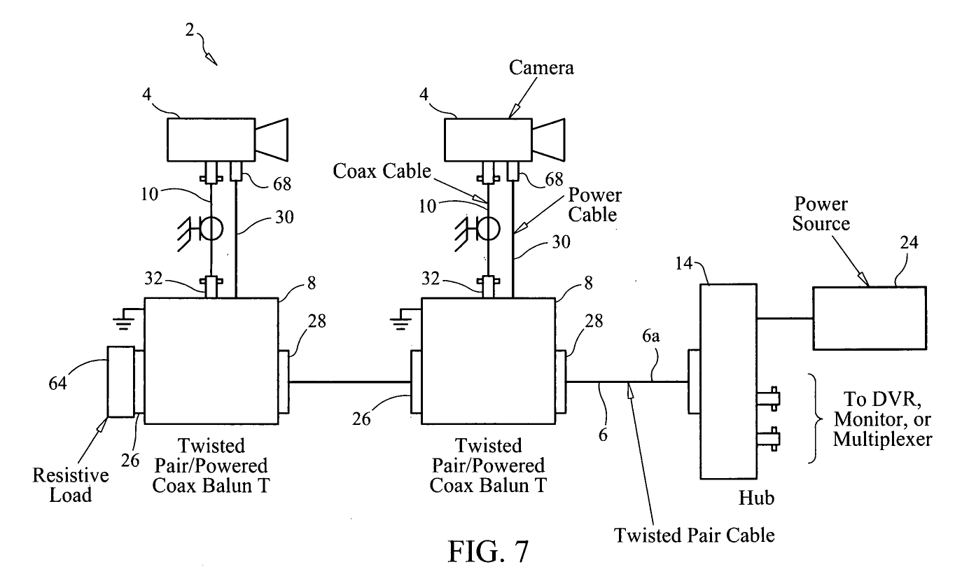

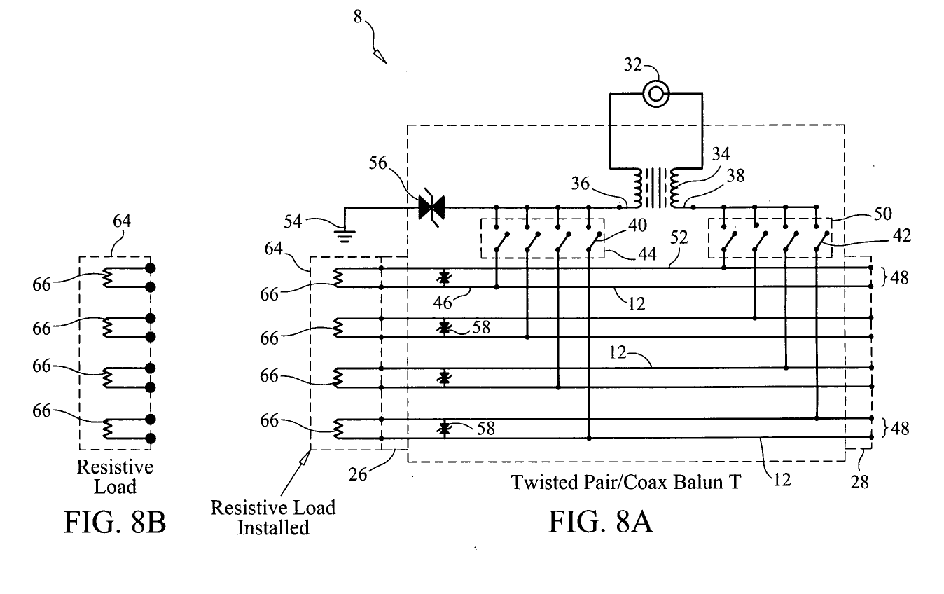

Alternatively, a resistive load 64 can be added to the “T” device 8 farthest from the hub 14, as shown in FIGS. 6, 7, 8A and 8B, to improve video quality. The resistive load 64 may be in the form of a multiple impedance termination, such as shown in FIG. 8A, coupled to one of the multiple pair, twisted pair cable connectors 26, 28 of the twisted pair-to-coax balun “T” devices 8, as shown in FIG. 8B. The termination 64 includes a plurality of resistors 66 or other impedances of a predetermined resistance, each resistor 66 being connected across a respective pair 48 of wires or transmission lines 12 within the “T” device 8. Again, like reference numbers shown in FIGS. 6, 7, 8A and 8B and in other figures refer to the same or similar components described previously and shown in the drawings.

The twisted pair-to-coax balun “T” devices 8 allow the video cameras 4 to be connected to a multiple pair, twisted pair cable or cables 6 in a “daisy chain” configuration. Not only does the use of the devices 8 arranged in the configuration described reduce the quantity of cabling required in a multiple video camera system, such as a surveillance system, but their use also minimizes the need of the more expensive coaxial cable 10 and uses the less expensive, multiple twisted pair cables 6 to carry the video signals and/or power signals. Also, it should be noted that what is meant herein as a “single”, multiple pair, twisted pair cable 6 is the arrangement shown in FIGS. 2 and 3, where the twisted pair-to-coax balun “T” devices 8 are connected in series with this cable 6 so that the “single” cable 6 is understood to comprise several cable segments interposed between and interconnecting adjacent “T” devices 8.

Accordingly, a video system 2 for transmitting video signals from a plurality of video cameras 4 formed in accordance with the present invention includes a plurality of video cameras 4, each video camera 4 generating an unbalanced video signal; a plurality of coaxial cables 10, each coaxial cable 10 being electrically coupled to a respective video camera 4 of the plurality of video cameras and carrying the unbalanced video signal from the respective video camera 4; a plurality of twisted pair-to-coax balun “T” devices 8, each balun “T” device 8 being electrically connected to a respective coaxial cable 10 of the plurality of coaxial cables and receiving the unbalanced video signal from a respective video camera 4, each twisted pair-to-coax balun “T” device 8 converting the unbalanced video signal from a respective video camera 4 to a balanced video signal; and at least one electrical cable 6 containing multiple twisted pairs of wires electrically interconnecting at least two twisted pair-to-coax balun “T” devices 8 of the plurality of twisted pair-to-coax balun “T” devices and selectively receiving on the twisted pairs of wires respective balanced video signals from the at least two twisted pair-to-coax balun “T” devices 8.

Preferably, each twisted pair-to-coax balun “T” device 8 of the video system 2 includes a coaxial connector 32 for electrical connection to a respective coaxial cable 10 coupled to a corresponding video camera 4 and receiving thereon an unbalanced video signal from the corresponding video camera 4; a first connector 26 and a second connector 28, the at least one electrical cable 6 containing multiple twisted pairs of wires being electrically connected to at least one of the first connector 26 and the second connector 28; a plurality of pairs 48 of first and second transmission lines 46, 52, each pair 48 of first and second transmission lines 46, 52 being electrically connected to the first connector 26 and the second connector 28; and a balun 34, the balun 34 including an input electrically coupled to the coaxial connector 32 and an output. The balun 34 converts the unbalanced video signal received by the twisted pair-to-coax balun “T” device 8 to a balanced video signal on the output. The output of the balun 34 includes a first leg 36 and a second leg 38. The first leg 36 is electrically coupled to the first transmission line 46 of at least one of the pairs 48 of first and second transmission lines 46, 52 of the plurality of pairs of transmission lines, and the second leg 38 is electrically coupled to the second transmission line 52 of the at least one of the pairs 48 of first and second transmission lines 46, 52 of the plurality of pairs of transmission lines.

Even more preferably, each twisted pair-to-coax balun “T” device 8 of the video system 2 further includes a first switch group 44 having at least one first switch 40, the at least one first switch 40 of the first switch group 44 being electrically interposed between and electrically connected to the first leg 36 of the balun output and the first transmission line 46 of the at least one of the pairs 48 of first and second transmission lines 46, 52; and a second switch group 50 having at least one second switch 42, the at least one second switch 42 of the second switch group 50 being electrically interposed between and electrically connected to the second leg 38 of the balun output and the second transmission line 52 of the at least one of the pairs 48 of first and second transmission lines 46, 52.

Furthermore, each of the at least one first switch 40 and the at least one second switch 42 respectively of the first switch group 44 and the second switch group 50 preferably includes a single pole, single or double throw switching device. Alternatively, the at least one first switch 40 of the first switch group 44 and the at least one second switch 42 of the second switch group 50 are ganged together to define a double pole, single or double throw switching device.

In another preferred form of the present invention, at least one of the twisted pair-to-coax balun “T” devices 8 of the video system 2 further includes at least one isolation device 56. The at least one isolation device 56 is electrically coupled to a ground potential and to at least one of the first leg 36 of the balun 34 and the second leg 38 of the balun 34. Furthermore, the at least one of the twisted pair-to-coax balun “T” devices 8 may further include at least one differential surge protection device 58. The at least one differential surge protection device 58 is electrically coupled to the first transmission line 46 of the at least one of the pairs 48 of first and second transmission lines 46, 52 and the second transmission line 52 of the at least one of the pairs 48 of first and second transmission lines 46, 52.

In another preferred form of the present invention, the at least one of the twisted pair-to-coax balun “T” devices 8 of the video system 2 may include a transmission line switch group 60 having at least a first switch 62a and a second switch 62b. The at least first switch 62a of the transmission line switch group 60 is electrically coupled in series with the first transmission line 46 of the at least one of the pairs 48 of first and second transmission lines 46, 52, and the at least second switch 62b of the transmission line switch group 60 being electrically coupled in series with the second transmission line 52 of the at least one of the pairs 48 of first and second transmission lines 46, 52. The at least first switch 62a and the at least second switch 62b are operable to selectively allow and disallow respective balanced video signals to pass through the first transmission line 46 and the second transmission line 52, respectively, of the at least one of the pairs 48 of first and second transmission lines 46, 52.

Even more preferably, the at least first switch 62a of the transmission line switch group 60 of at least one of the twisted pair-to-coax balun “T” devices 8 of the video system 2 and the at least second switch 62b of the transmission line switch group 60 of the at least one of the twisted pair-to-coax balun “T” devices 8 are ganged together to define a double pole, single or double throw switching device. The at least first switch 62a and the at least second switch 62b of the transmission line switch group 60 of at least one of the twisted pair-to-coax balun “T” devices 8 is preferably electrically interposed respectively in the first transmission line 46 and the second transmission line 52 of the at least one of the pairs 48 of first and second transmission lines 46, 52 between the first connector 26 and the second connector 28.

In another form of the present invention, the at least one of the twisted pair-to-coax balun “T” devices 8 of the video system 2 further includes a resistive load 64. The resistive load 64 is electrically coupleable to one of the first connector 26 and the second connector 28. The resistive load 64 preferably includes a plurality of resistive devices 66. Each resistive device 66 has a selected impedance. A respective resistive device 66 of the plurality of resistive devices is electrically coupled between the first transmission line 46 and the second transmission line 52 of corresponding pairs 48 of first and second transmission lines 46, 52 when the resistive load 64 is electrically coupled to the at least one of the first connector 26 and the second connector 28.

In yet another form of the present invention, the video system 2 may additionally include a hub 14, the hub 14 being electrically coupled to at least one of the twisted pair-to-coax balun “T” devices 8; and at least another electrical cable 6a containing multiple twisted pairs of wires, the at least another electrical cable 6a electrically interconnecting the hub 14 to the at least one of the twisted pair-to-coax balun “T” devices 8.

Furthermore, the video system 2 of the present invention may include at least one of a monitor 20, a digital video recorder 16 and a multiplexer 22. The at least one of the monitor 20, digital video recorder 16 and multiplexer 22 is electrically coupled to the hub 14.

Additionally, each video camera 4 of the plurality of video cameras of the video system 2 may include a power input 68 for receiving a power signal. At least one of the twisted pairs of wires of the electrical cable 6 carries a power signal thereon. The power signal carried on the at least one of the twisted pairs of wires of the electrical cable 6 is provided to at least one of the two twisted pair-to-coax balun “T” devices 8. The at least one of the two twisted pair-to-coax balun “T” devices 8 provides the power signal to the power input 68 of a respective video camera 4 to which the at least one of the two twisted pair-to-coax balun “T” devices 8 is electrically coupled.

Furthermore, in accordance with the present invention, a method of transmitting video signals from a plurality of video cameras 4 in a video system 2 includes the steps of generating by the plurality of video cameras 4 unbalanced video signals; receiving the unbalanced video signals over coaxial cables 10 by a plurality of twisted pair-to-coax balun “T” devices 8, each twisted pair-to-coax balun “T” device 8 including a balun 34 having an input and an output and a connector 26, 28 electrically coupled to the balun output; converting the unbalanced video signal received by a respective twisted pair-to-coax balun “T” device 8 to a balanced video signal and providing the balanced video signal on the connector 26, 28; and electrically connecting the connector 26, 28 to an electrical cable 6 containing multiple twisted pairs of wires to receive on at least one of the twisted pairs of wires the respective balanced video signal from the corresponding twisted pair-to-coax balun “T” device 8 to which the electrical cable 6 is electrically connected.

Although illustrative embodiments of the present invention have been described herein with reference to the accompanying drawings, it is to be understood that the invention is not limited to those precise embodiments, and that various other changes and modifications may be effected therein by one skilled in the art without departing from the scope or spirit of the invention.

What is claimed is:

1. A video system for transmitting video signals from a plurality of video cameras, which comprises:
a plurality of video cameras, each video camera generating an unbalanced video signal;
a plurality of coaxial cables, each coaxial cable being electrically coupled to a respective video camera of the plurality of video cameras and carrying the unbalanced video signal from the respective video camera;
a plurality of twisted pair-to-coax balun “T” devices, each balun “T” device being electrically connected to a respective coaxial cable of the plurality of coaxial cables and receiving the unbalanced video signal from a respective video camera, each twisted pair-to-coax balun “T” device converting the unbalanced video signal from a respective video camera to a balanced video signal; and
at least one electrical cable containing multiple twisted pairs of wires electrically interconnecting at least two twisted pair-to-coax balun “T” devices of the plurality of twisted pair-to-coax balun “T” devices and selectively receiving on the twisted pairs of wires respective balanced video signals from the at least two twisted pair-to-coax balun “T” devices.

2. A video system as defined by claim 1, wherein each twisted pair-to-coax balun “T” device comprises:
a coaxial connector for electrical connection to a respective coaxial cable coupled to a corresponding video camera and receiving thereon an unbalanced video signal from the corresponding video camera;
a first connector and a second connector, the at least one electrical cable containing multiple twisted pairs of wires being electrically connected to at least one of the first connector and the second connector;
a plurality of pairs of first and second transmission lines, each pair of first and second transmission lines being electrically connected to the first connector and the second connector; and
a balun, the balun including an input electrically coupled to the coaxial connector and an output, the balun converting the unbalanced video signal received by the twisted pair-to-coax balun “T” device to a balanced video signal on the output, the output of the balun including a first leg and a second leg, the first leg being electrically coupled to the first transmission line of at least one of the pairs of first and second transmission lines of the plurality of pairs of transmission lines, the second leg being electrically coupled to the second transmission line of the at least one of the pairs of first and second transmission lines of the plurality of pairs of transmission lines.

3. A video system as defined by claim 2, wherein each twisted pair-to-coax balun “T” device further comprises:
a first switch group having at least one first switch, the at least one first switch of the first switch group being electrically interposed between and electrically connected to the first leg of the balun output and the first transmission line of the at least one of the pairs of first and second transmission lines; and
a second switch group having at least one second switch, the at least one second switch of the second switch group being electrically interposed between and electrically connected to the second leg of the balun output and the second transmission line of the at least one of the pairs of first and second transmission lines.

4. A video system as defined by claim 3, wherein each of the at least one first switch and the at least one second switch respectively of the first switch group and the second switch group includes a single pole, single or double throw switching device.

5. A video system as defined by claim 3, wherein the least one first switch of the first switch group and the at least one second switch of the second switch group are ganged together to define a double pole, single or double throw switching device.

6. A video system as defined by claim 2, wherein at least one of the twisted pair-to-coax balun “T” devices further comprises:
at least one isolation device, the at least one isolation device being electrically coupled to a ground potential and to at least one of the first leg of the balun and the second leg of the balun.

7. A video system as defined by claim 2, wherein at least one of the twisted pair-to-coax balun “T” devices further comprises:
at least one differential surge protection device, the at least one differential surge protection device being electrically coupled to the first transmission line of the at least one of the pairs of first and second transmission lines and the second transmission line of the at least one of the pairs of first and second transmission lines.

8. A video system as defined by claim 2, wherein at least one of the twisted pair-to-coax balun “T” devices further comprises:
a transmission line switch group having at least a first switch and a second switch, the at least first switch of the transmission line switch group being electrically coupled in series with the first transmission line of the at least one of the pairs of first and second transmission lines, the at least second switch of the transmission line switch group being electrically coupled in series with the second transmission line of the at least one of the pairs of first and second transmission lines, the at least first switch and the at least second switch being operable to selectively allow and disallow respective balanced video signals to pass through the first transmission line and the second transmission line, respectively, of the at least one of the pairs of first and second transmission lines.

9. A video system as defined by claim 8, wherein the at least first switch of the transmission line switch group of at least one of the twisted pair-to-coax balun “T” devices and the at least second switch of the transmission line switch group of the at least one of the twisted pair-to-coax balun “T” devices are ganged together to define a double pole, single or double throw switching device.

10. A video system as defined by claim 8, wherein the at least first switch and the at least second switch of the transmission line switch group of at least one of the twisted pair-to-coax balun “T” device is electrically interposed respectively in the first transmission line and the second transmission line of the at least one of the pairs of first and second transmission lines between the first connector and the second connector.

11. A video system as defined by claim 2, wherein at least one of the twisted pair-to-coax balun “T” devices further comprises:
a resistive load, the resistive load being electrically coupleable to one of the first connector and the second connector.

12. A video system as defined by claim 11, wherein the resistive load includes a plurality of resistive devices, each resistive device having a selected impedance, a respective resistive device of the plurality of resistive devices being electrically coupled between the first transmission line and the second transmission line of corresponding pairs of first and second transmission lines when the resistive load is electrically coupled to the at least one of the first connector and the second connector.

13. A video system as defined by claim 1, which further comprises:
a hub, the hub being electrically coupled to at least one of the twisted pair-to-coax balun “T” devices; and
at least another electrical cable containing multiple twisted pairs of wires, the at least another electrical cable electrically interconnecting the hub to the at least one of the twisted pair-to-coax balun “T” devices.

14. A video system as defined by claim 13, which further comprises:
at least one of a monitor, a digital video recorder and a multiplexer, the at least one of the monitor, digital video recorder and multiplexer being electrically coupled to the hub.

15. A video system as defined by claim 1, wherein each video camera of the plurality of video cameras includes a power input for receiving a power signal;
wherein at least one of the twisted pairs of wires of the electrical cable carries a power signal thereon; and
wherein the power signal carried on the at least one of the twisted pairs of wires of the electrical cable is provided to at least one of the two twisted pair-to-coax balun “T” devices, the least one of the two twisted pair-to-coax balun “T” devices providing the power signal to the power input of a respective video camera to which the at least one of the two twisted pair-to-coax balun “T” devices is electrically coupled.

16. A twisted pair-to-coax balun “T” device for use in a video system having a plurality of video cameras, which comprises:
a coaxial connector for electrical connection to a respective coaxial cable coupled to a corresponding video camera and receiving thereon an unbalanced video signal from the corresponding video camera;
a first connector and a second connector, the first connector and the second connector for electrical connection to an electrical cable containing multiple twisted pairs of wires;
a plurality of pairs of first and second transmission lines, each pair of first and second transmission lines being electrically connected to the first connector and the second connector; and
a balun, the balun including an input electrically coupled to the coaxial connector and an output, the balun converting the unbalanced video signal received by the twisted pair-to-coax balun “T” device to a balanced video signal on the output, the output of the balun including a first leg and a second leg, the first leg being electrically coupled to the first transmission line of at least one of the pairs of first and second transmission lines of the plurality of pairs of transmission lines, the second leg being electrically coupled to the second transmission line of the at least one of the pairs of first and second transmission lines of the plurality of pairs of transmission lines.

17. A twisted pair-to-coax balun “T” device as defined by claim 16, which further comprises:
a first switch group having at least one first switch, the at least one first switch of the first switch group being electrically interposed between and electrically connected to the first leg of the balun output and the first transmission line of the at least one of the pairs of first and second transmission lines; and
a second switch group having at least one second switch, the at least one second switch of the second switch group being electrically interposed between and electrically connected to the second leg of the balun output and the second transmission line of the at least one of the pairs of first and second transmission lines.

18. A twisted pair-to-coax balun “T” device as defined by claim 16, which further comprises:
at least one isolation device, the at least one isolation device being electrically coupled to a ground potential and to at least one of the first leg of the balun and the second leg of the balun.

19. A twisted pair-to-coax balun “T” device as defined by claim 16, which further comprises:
at least one differential surge protection device, the at least one differential surge protection device being electrically coupled to the first transmission line of the at least one of the pairs of first and second transmission lines and the second transmission line of the at least one of the pairs of first and second transmission lines.

20. A twisted pair-to-coax balun “T” device as defined by claim 16, which further comprises:
a transmission line switch group having at least a first switch and a second switch, the at least first switch of the transmission line switch group being electrically coupled in series with the first transmission line of the at least one of the pairs of first and second transmission lines, the at least second switch of the transmission line switch group being electrically coupled in series with the second transmission line of the at least one of the pairs of first and second transmission lines, the at least first switch and the at least second switch being operable to selectively allow and disallow respective balanced video signals to pass through the first transmission line and the second transmission line, respectively, of the at least one of the pairs of first and second transmission lines.

21. A twisted pair-to-coax balun “T” device as defined by claim 16, which further comprises:
a resistive load, the resistive load being electrically coupleable to one of the first connector and the second connector, the resistive load including a plurality of resistive devices, each resistive device having a selected impedance, a respective resistive device of the plurality of resistive devices being electrically coupled between the first transmission line and the second transmission line of corresponding pairs of first and second transmission lines when the resistive load is electrically coupled to the at least one of the first connector and the second connector.

22. A method of transmitting video signals from a plurality of video cameras in a video system, which comprises the steps of:
generating by the plurality of video cameras unbalanced video signals;
receiving the unbalanced video signals over coaxial cables by a plurality of twisted pair-to-coax balun “T” devices, each twisted pair-to-coax balun “T” devices including a balun having an input and an output and a connector electrically coupled to the balun output;
converting the unbalanced video signal received by a respective twisted pair-to-coax balun “T” device to a balanced video signal and providing the balanced video signal on the connector; and
electrically connecting the connector to an electrical cable containing multiple twisted pairs of wires to receive on at least one of the twisted pairs of wires the respective balanced video signal from the corresponding twisted pair-to-coax balun “T” device to which the electrical cable is electrically connected.
